(19) United States
(12) Patent Application Publication
(10) Pub. No.: US 2012/0250296 A1
(43) Pub. Date: Oct. 4, 2012

(54) SYSTEM AND METHOD FOR ILLUMINATING A SPACE WITH INCREASED APPLICATION EFFICIENCY

(76) Inventors: Min-Hao Michael Lu, Castro Valley, CA (US); Peter Y. Y. Ngai, Alamo, CA (US); Jeannine M. Fisher, Oakland, CA (US)

(21) Appl. No.: 13/407,670

(22) Filed: Feb. 28, 2012

Related U.S. Application Data
(60) Provisional application No. 61/447,657, filed on Feb. 28, 2011.
(60) Provisional application No. 61/486,698, filed on May 16, 2011.

(51) Int. Cl. F21S 8/04; H05K 13/00

(52) U.S. Cl. 362/147; 29/592.1

(57) ABSTRACT

A system and method for illuminating a space includes sectioning the space to be illuminated into lighting requirement areas having different illumination requirements. The area of each lighting requirement area is determined and then the minimum number of lumens required to illuminate each lighting requirement area is determined. A plurality of planar, low lumen, small footprint lighting modules are configured overhead the space in different placement densities including high placement densities, wherein a different amount of lumens are delivered into the space from different overhead placement positions depending on the placement densities of the lighting modules at their placement positions. The number and placement density of the lighting modules needed over each lighting requirement area is determined so as to produce a desired number of lumens for such lighting requirement area.

### CROSS-REFERENCE TO RELATED APPLICATIONS

This application claims the benefit of U.S. Provisional Patent Application No. 61/447,657 filed Feb. 28, 2011, and U.S. Provisional Application No. 61/486,698, filed May 16, 2011, both of which are incorporated herein by reference.

### FIELD OF INVENTION

The present invention generally relates to systems and methods for lighting indoor spaces and more particularly to lighting indoor spaces having task and non-task areas having different illumination requirements.

### BACKGROUND OF INVENTION

Most non-residential commercial and institutional indoor lighting is uniform, targeted for the most demanding visual tasks. This practice is driven by ingrained thinking and limitations of conventional lighting systems, and results in a waste of installation materials and energy. While lighting designers are concerned with energy efficiency, they do not normally think of application efficiency (defined below) in the course of their design work. Rather, selection and specification of lighting systems is predicated upon meeting a set of pre-determined design criteria such as illuminance levels, luminance ratios, maximum lighting power density, ease of maintenance, light source color characteristics, initial cost, maintenance and operating costs, etc. Typically, the designer will select luminaires, locate them on a set of reflected ceiling plans, then test the design against the pre-determined design criteria. Often, multiple approaches are considered, and based on aesthetic parameters, architectural considerations, and compromises/re-prioritization of the design criteria, a final design is selected. This final design will often continue being refined throughout the construction process.

Especially in large spaces, lighting is attached to the ceiling in one fashion or another. The primary reason for this is a practical one—lighting systems require electricity, and the ceiling conceals wiring and any supporting structure.

While lighting designers may know exactly how the end-user will be using a space and the kinds of tasks the user will be performing, during the course of the design for a project the lighting designer cannot be assured that end-users' needs are static or that a space will always be configured in the same way. This need to plan for long-term flexibility has led to the standard practice of implementing lighting systems that approximate uniform illumination throughout a space at lighting levels that are targeted to provide enough light for the most demanding visual tasks anticipated during initial design.

Except for specialty areas, end-users (particularly at large-scale facilities) shy away from accepting lighting systems that are complex in nature, comprised of multiple layers of light and a myriad of luminaire types that might otherwise be able to provide lighting better tuned to meet user requirements.

The existing approaches to providing overhead lighting in non-residential environments make it difficult meet increasingly restrictive energy codes, building rating systems and legislation that encourage “beyond code” design. The invention described herein overcomes such disadvantages by providing a system and method for illuminating a space with overhead lighting elements that can be advantageously deployed to provide different levels of illumination at different areas within the space to meet different illumination requirements within the space.

### DESCRIPTION OF THE DRAWINGS

FIG. 1 is a pictorial representation of an open plan office having task areas, non-task areas and circulation areas, and is used to illustrate the method of the invention.

FIG. 2 is a chart showing the application efficiency of various types of conventional lighting systems.

FIG. 3 is a chart showing the application efficiency of two solid state lighting systems.

FIG. 4 is a chart showing the application efficiency of a lighting system that includes discrete low-luminance OLED panels.

FIG. 5 is a table summarizing quantitative data obtained for specific lighting systems.

FIG. 6 is a table showing the percent of ceiling area coverage for specific lighting systems.

FIG. 7A is a bottom perspective view of a lighting system having driver panels and low luminance OLED lighting modules that can be configured in and beneath a grid ceiling to provide small footprint low luminance lighting modules in different placement densities, including high placement densities, for carrying out the method and providing a lighting system in accordance with the invention.

FIG. 7B is an exploded bottom perspective view thereof.

FIG. 8A shows one configuration of light modules on a grid ceiling that can be created with the driver panels and light modules illustrated in FIGS. 7A and 7B.

FIG. 8B shows another pattern of light modules on a grid ceiling that can be created with the driver panels and light modules illustrated in FIGS. 7A and 7B.

FIG. 9 is a bottom perspective view of another version of the grid ceiling driver panel shown in FIGS. 7A and 7B, showing an alternative configuration of the light module connectors in the bottom surface of the driver panel.

FIG. 10 shows a pattern of light modules on a grid ceiling that can be created with driver panels such as shown in FIG. 9.

FIGS. 11A and 11B are bottom plan views of panel drivers for a grid ceiling such as shown in FIGS. 7A and 7B, showing yet further alternative configurations for the light module connectors.

FIG. 12 shows an exemplary clustering of light modules on a grid ceiling that can be created with driver panels such as shown in FIGS. 11A and 11B.

### DETAILED DESCRIPTION

The invention provides a system and method of increasing the application efficiency of an indoor lighting system. Application efficiency is based on determining how well the luminaires installed in indoor spaces are utilized in delivering light where it is actually needed to provide adequate illumination levels at task and non-task locations. Because different visual tasks are typically performed at different locations in any given indoor space, uniform lighting cannot achieve a high level of application efficiency.

A majority of overhead lighting currently in use in commercial and institutional lighting applications fall into six different categories. Below, the application efficiency of these six categories of overhead lighting are evaluated and compared to an overhead lighting system in accordance with the invention, and in particular, to a lighting system that uses small footprint OLED lighting modules comprised of discrete low-luminance OLED panels approximately 4 inches square with a luminance of 3000 cd/m2. (Such a small footprint OLED lighting module is described in greater detail later in this specification.)

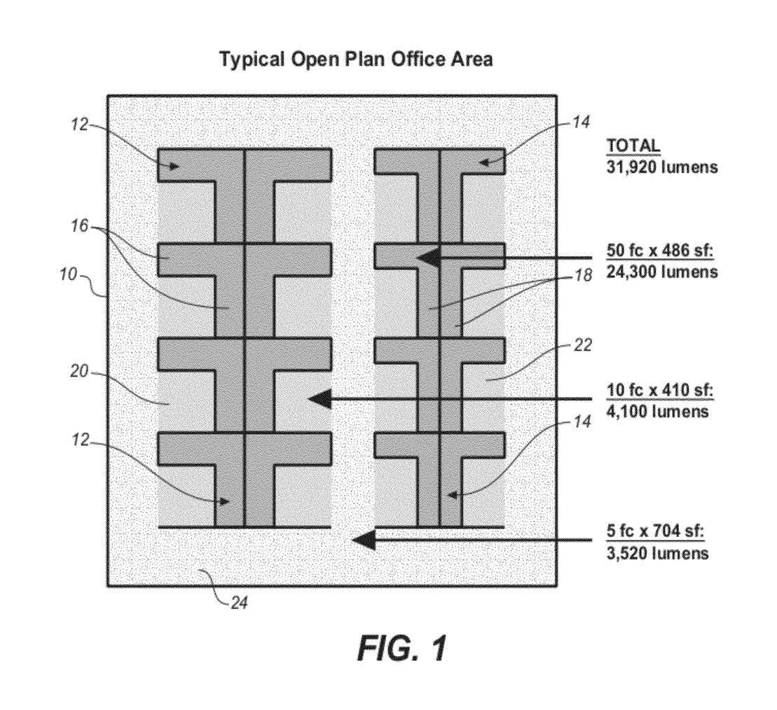

A space can be evaluated to determine how many lumens would be needed if the lighting system delivered exactly the amount of lumens in the exact location—100% application efficiency. To do so, the space is sectioned by recommended task illumination requirements (in footcandles or lumens per square foot). Each task area (in square feet) is then multiplied by the illumination requirement to calculate the minimum number of lumens needed to light each area if the lighting system achieved 100% application efficiency. The lumens for each task area are added to arrive at a total minimum number of lumens needed to light the entire space if the lighting system achieved 100% application efficiency. FIG. 1 shows this process for a typical open plan office area.

FIG. 1 depicts a 40′×40′ room with a 9′ ceiling denoted by the numeral 10. The larger workstations, denoted by the numeral 12, are 8′×8′ in area with 5′ high partition panels. The smaller workstations, denoted by the numeral 14, are 6′×8′ with 3.5° high partition panels. The darkest shaded areas 16, 18 are task areas such as desk surfaces where demanding visual tasks occur. The medium shaded areas 20, 22 are where less demanding visual tasks will occur, or non-task areas. The lightest stippled areas 24 are circulation areas, which only require enough illumination for finding your way through the area.

In this sample of an open plan office area a lighting system that delivers 31,920 lumens in the right locations could achieve 100% application efficiency. If the comparison is limited to overhead lighting systems that provide the right number of lumens in the task areas, application efficiency becomes a test of the extent to which the lighting system is over-lighting non-task and circulation areas. Mathematically, then, application efficiency can be defined using the following equation:

Theoretical/Actual×100, expressed in %, where
Actual=the initial light source lumens utilized by the lighting system under consideration
Theoretical=minimum lumens required to achieve 100% application efficiency

For the lighting system comparison data discussed below, the lighting analysis results are based on a consistent set of calculation assumptions applied in commercially available lighting calculation and visualization software using a Radiosity calculation engine. Light source lumen ratings are obtained from luminaire photometric test data. Absolute photometry is used in the case of any solid state lighting luminaires. Results consider inter-reflected light and are based on a specific luminaire photometric performance. Since specific luminaire photometric performance will vary based on manufacturer and model number, lamping, ballasting, and other multiple variables, these results should be viewed as approximations only in making broad comparisons of lighting system classifications as intended in the context of this disclosure. Design details that are assumed in the analysis would be considered typical parameters for an office lighting applications.

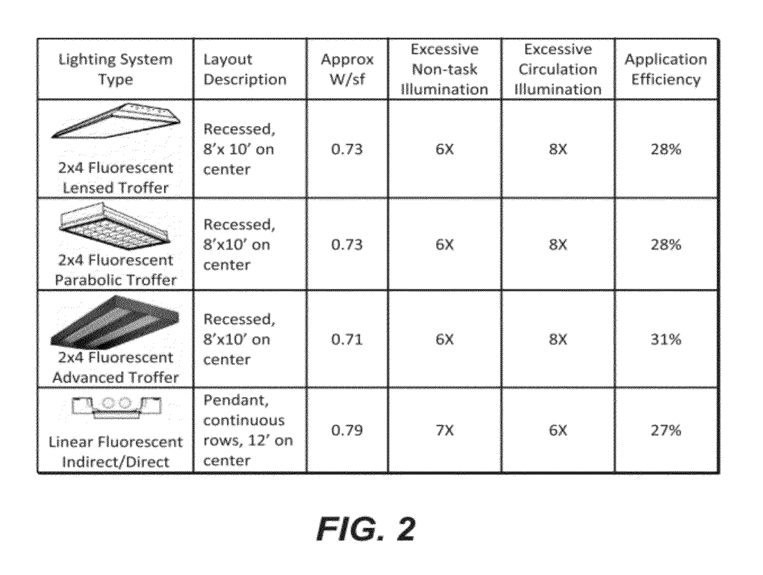

To compare conventional lighting systems, reference is first made to the application efficiency of conventional lighting systems as described in the chart in FIG. 2. In the case of these conventional lighting systems, application efficiency ranges between 27 and 31 percent. These systems are considered as a baseline performance.

Historically, fluorescent lensed troffers have been a prevalent type of general lighting used in commercial and institutional lighting since the 1960s. While this type of lighting provides luminous walls, the aesthetic of the luminaire is lackluster and the low cost associates this luminaire type with spaces that are cheap or utilitarian. The layout must relate to the ceiling and be regular in pattern to avoid creating a sense of visual clutter.

Parabolic troffers became dominant during the proliferation of early personal computers in the 1980s when software and display technology relied upon dark backgrounds and light characters. These screen types were very unforgiving to high angle glare. While the parabolic troffer solved this problem, it created dark walls and a dark ceiling, resulting in an overall gloomy environment. In addition, the open louvers allowed for direct viewing of the fluorescent lamp, resulting in overhead glare. Like the lensed troffer, the layout must relate to the ceiling and be regular in pattern. Advanced troffers became prevalent in the 1990s as software and display technology evolved. These troffers improved upon parabolic troffers by re-introducing volumetric brightness and providing more architectural styling, and because of the improvements in screen technology, the severe cut-off of the parabolic troffer was no longer needed. As with other troffer-type lighting systems, the layout for the advanced type must be regular in pattern.

As an alternative to recessed lighting, several types of linear fluorescent pendant systems are available, including indirect, indirect-direct, direct-indirect, and even direct. For most ceiling heights, indirect-direct provides the best balance of glare-free indirect illumination coupled with some direct illumination to provide modeling of three-dimensional objects, including facial features. These systems tend to be highly efficient as well, and the focus has been on this type of pendant lighting for the analysis. Indirect-direct linear fluorescent lighting comes in many different luminaire shapes and designers have more flexibility in placement (row spacing). Although there is more design freedom, layouts tend to be regular to provide a visual order to the space. When given a choice (i.e. sufficient ceiling height and budget), many lighting designers will recommend this type of lighting.

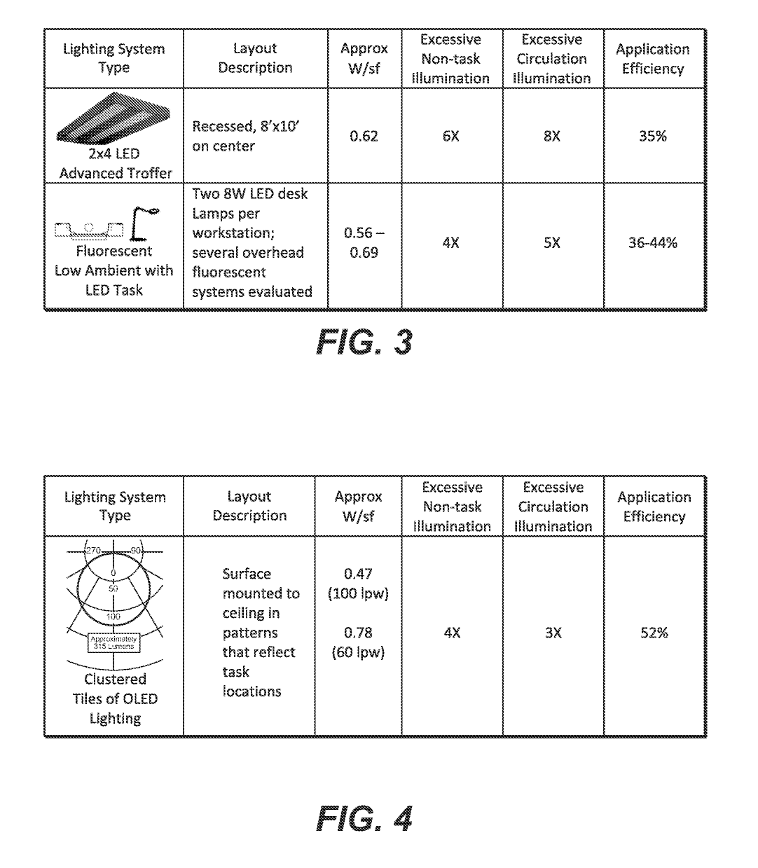

Recent advances in solid state lighting have provided additional system approaches, which, at the very least, reduce installed lighting power density. Two such systems are presented in FIG. 3.

For these newer systems, approximately a 14% reduction in lighting power density is seen as a result of utilizing systems that are based on solid state lighting. Application efficiency improves 39%, on average.

The LED Advanced Troffer provides a quality of light equal to its fluorescent counterpart for basic light distribution attributes. With the LED light source, additional end-user benefits are offered, including ease of digital control, lumen maintenance at no additional cost, and reduced maintenance.

Task ambient systems have long been touted as a way to improve application efficiency. In practice, these systems have been generally insufficient in terms of providing proper task illumination, largely because fluorescent-based task lights provide too much light, unless they are dimmed. (For fluorescent-based systems, dimming decreases efficiency and adds cost.) However, using LED, the task illumination can be more appropriately added while still achieving recommended luminance ratios within the immediate task area.

As far as the overhead lighting is concerned, the same types of conventional fluorescent lighting can be used by adjusting combinations of lamping and spacing to provide a lower quantity of ambient light. In this disclosure, evaluated are single lamp versions of indirect-direct pendants (12′ on center), 1×4 parabolic troffers (6′×8′ on center), and 2×4 advanced troffers (8′×10′ on center), resulting in the range of values reported above. End-users tend to rate these systems highly because they prefer having individual control. However, in order to achieve these levels of user preference, these systems must be designed with caution because even high quality LED task lights are prone to creating hot spots on the task surface, and the overall lighting quality can suffer. The de-coupling of the lighting system means that two systems are needed to do one job. In addition, when the ambient system is designed to meet low lighting power density targets, adequate wall brightness becomes a concern, and a third lighting system must be added.

Both of these newer lighting systems will come at a cost premium over the baseline conventional lighting systems discussed in the prior section.

FIG. 4 presents the results of an implementation of a small footprint lighting module in accordance with the invention, wherein the lighting module is in the form of a cluster of discrete low-luminance OLED panels. As above-mentioned, the low luminance OLED panels are square panels approximately 4 inches square with a luminance of 3000 cd/m2. The specific implementation discussed herein configures OLED panels in clusters of five to provide a lighting module that produces light from a small foot print that can be positioned in an overhead lighting system with respect to designated task locations.

Of all of the systems evaluated, the application efficiency improves by a factor of 18-93% for the small footprint lighting module that uses discrete low-luminance OLED panels. Over half of the lumens generated are utilized in delivering the light where it is needed, resulting in energy savings of 16-41% compared to the alternative lighting approaches discussed here, and over 50% compared to ASHRAE 90.1-2010 allowed lighting power density. Even considering the immediate term anticipated luminous efficacy of 60 lumens per watt, lighting power density is on par with currently available lighting systems.

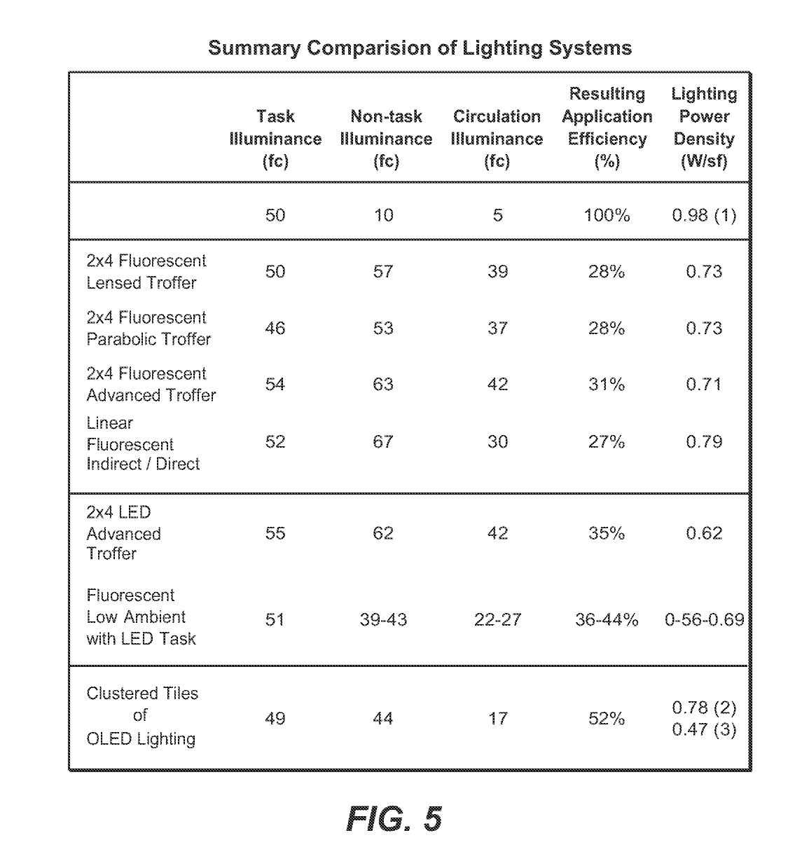

A summary of all lighting systems is presented in the table in FIG. 5, wherein the minimum required illuminance in footcandles required for the task, non-task and circulation areas as represented in FIG. 1 is shown in the first row of the chart, and the actual illuminance produced by the indicated lighting systems discussed above and application lighting efficiency for each lighting system is shown in the rows below.

The quantities of vertical illumination produced by each of these systems have also been evaluated. Vertical illumination increases the psychological perception of brightness in a space and mitigates harsh shadows. In this regard, the clustered OLED panels perform better than a majority of the systems that have been analyzed. When evaluating the shape of the photometric distribution curve of the OLED lighting module, it is seen that it emulates the type of photometric distribution associated with “volumetric” lighting systems, generally considered to be of above average quality in producing adequate vertical illumination.

The low luminance of the OLED panels is favorable for minimizing direct glare. Some of the conventional lighting systems may show spot luminance readings upwards of 9,000 cd/m2, or over 3 times the brightness of the OLED lighting system. In addition, the OLED panels represent less than 10% of the lumen package of a conventional overhead luminaire. This attribute creates small packets of light that allow complete customization for luminaire placement. Because the OLED lighting modules can be placed in locations that follow where tasks occur, the lighting system will have a stronger relationship with the occupant, compared to the other lighting systems that relate more to the ceiling. For this reason, the OLED lighting system will enhance a feeling of personalization and facilitate control by individual occupants.

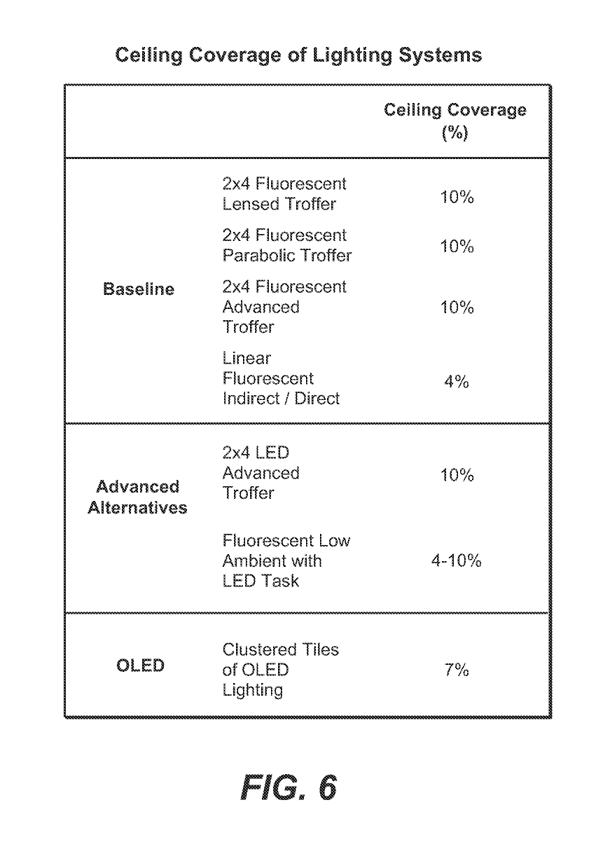

Each OLED panel, in terms of lumen output, is like dividing a fluorescent lamp into 40 or 50 pieces, allowing for an unprecedented refinement of lighting control, whether that be by switching or dimming or both. Add to that the possibility of color temperature (or saturated color) tuning, and the OLED lighting system can create dynamic and interactive systems for a host of commercial and institutional lighting markets, including offices, schools, retail, and hospitality environments. Many who conceptualize the use of OLED lighting in interior commercial and institutional lighting applications envision that very large areas of the ceiling will need to be covered by OLED tiles, leading to the conclusion that larger panel size is advantageous. However, when the data in the table in FIG. 6 is reviewed, it can be see that the opposite is true. The illuminated area of OLED tiles required to provide adequate illumination is actually less than the illuminated area consumed by traditional ceiling-recessed lighting systems, by as much as a 30% reduction. This finding yields several advantages for the OLED panel manufacturer, including higher yield, lower manufacturing cost, and ultimately greater volume for fewer standard panel sizes.

Compared to other types of lighting systems predominantly used for commercial and institutional lighting, discrete low-luminance lighting modules such as the lighting tiles of OLED lighting can create a lighting system that makes significant improvements in application efficiency. Additional benefits include reduced glare, increased energy efficiency, design freedom, opportunities with controls, practicality, and higher levels of occupant comfort. Discrete low-luminance lighting modules such as the tiles of OLED lighting will provide designers with a simple overhead lighting system to meet the challenges of energy efficient design requirements.

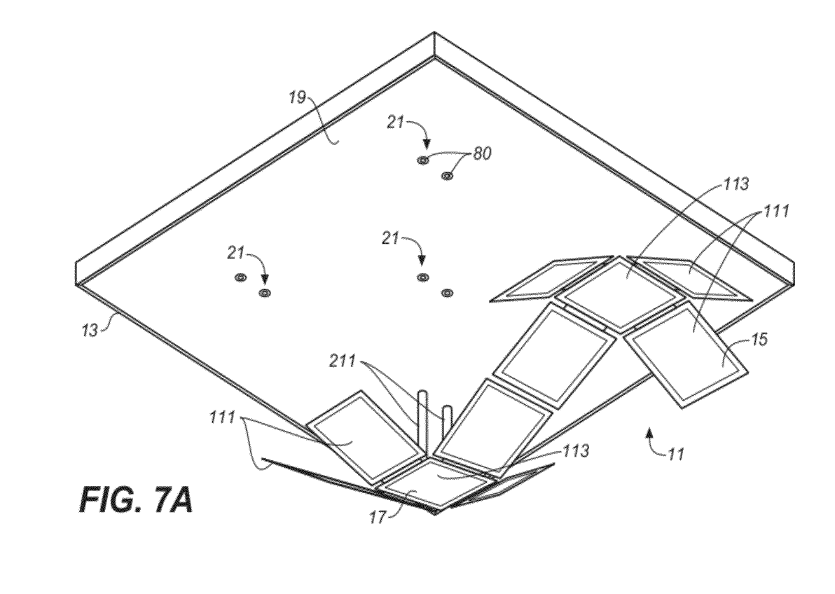

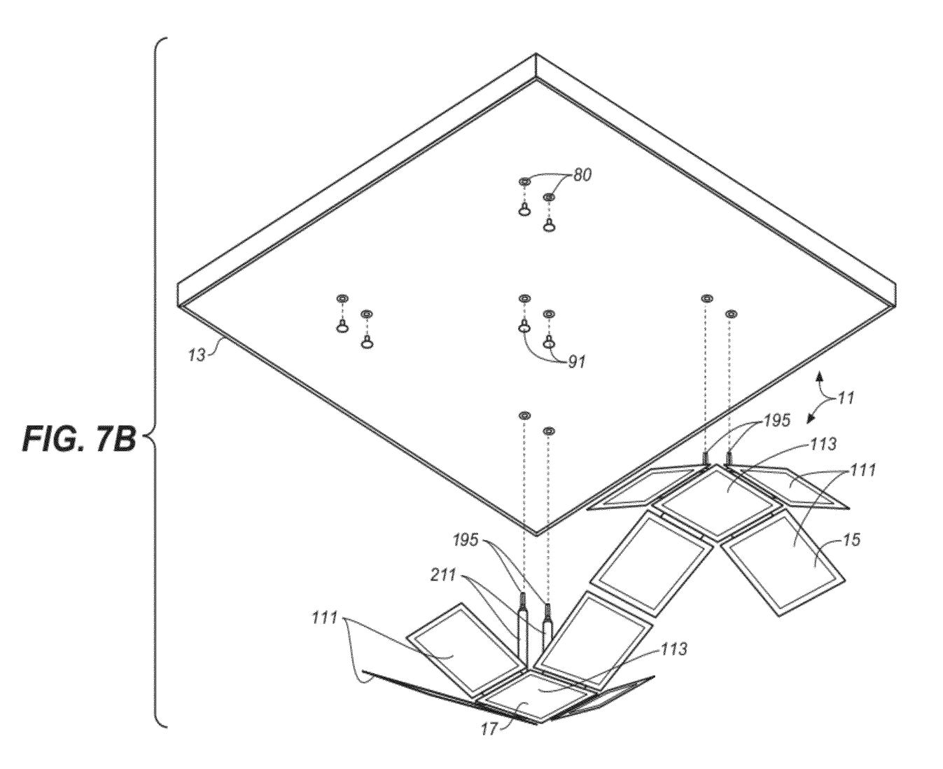

FIGS. 7A and 7B show a lighting module having a cluster low luminance OLED panels as above-described, which can be used to provide a ceiling lighting system to carry out the method of the invention in spaces with grid ceilings, and particularly which can be configured beneath a grid ceiling in different placement densities including high placement densities. The ceiling lighting system, denoted by the number 11, includes at least one and suitably a plurality of ceiling driver panels 13 and at least one and preferably a plurality of small footprint light modules 15, 17 that can be removably connected to the driver panels. Each lighting module includes a cluster of five OLED panels, namely, outer OLED panels 111 and a center OLED panel 113, and suitably has a footprint of approximately one foot by one foot. The outer OLED panels 111 of each module are seen to be angled relative to its center panel 113, with a suitable angle being about 25 degrees. Suitable electrical connectors, such as banana plugs 195, can be provided on a support frame for the center OLED panel on the non-light emitting side the panel. It is seen that the light modules can be configured in a panel-up or panel-down configuration relative to the connector side of the center panel. In the panel-up module 17, extenders 211 are suitably provided to provide and stand-off from the ceiling to accommodate the turned up outer OLED panels of that lighting module. While the light modules are described herein as being comprised of OLED panels, other low-luminance light sources could be used, for example, flat edge-lit LED waveguide panels or other large-area diffuse light sources such as QDLED or embedded nano crystals of III-V semiconductors.

The driver panel 13 for the lighting modules has a planar low profile form factor and fits within a grid opening of the grid framework of the grid ceiling system, and becomes part of the grid ceiling. The driver panel has a bottom with an exposed bottom surface 19, which can simulate a ceiling tile of a grid ceiling system, but which could be provided with a wide variety of surface characteristics, including surface treatments for particular desired aesthetic effects. It also has at least one and preferably more than one electrical connector 21, such as a banana plug sockets 80, on its bottom surface to which the light modules 15, 17 can be operatively connected. Each connector of the driver panel provides a selectable connection point on the grid ceiling at which a small footprint low luminance light module can be positioned for creating a ceiling lighting system in accordance with the invention.

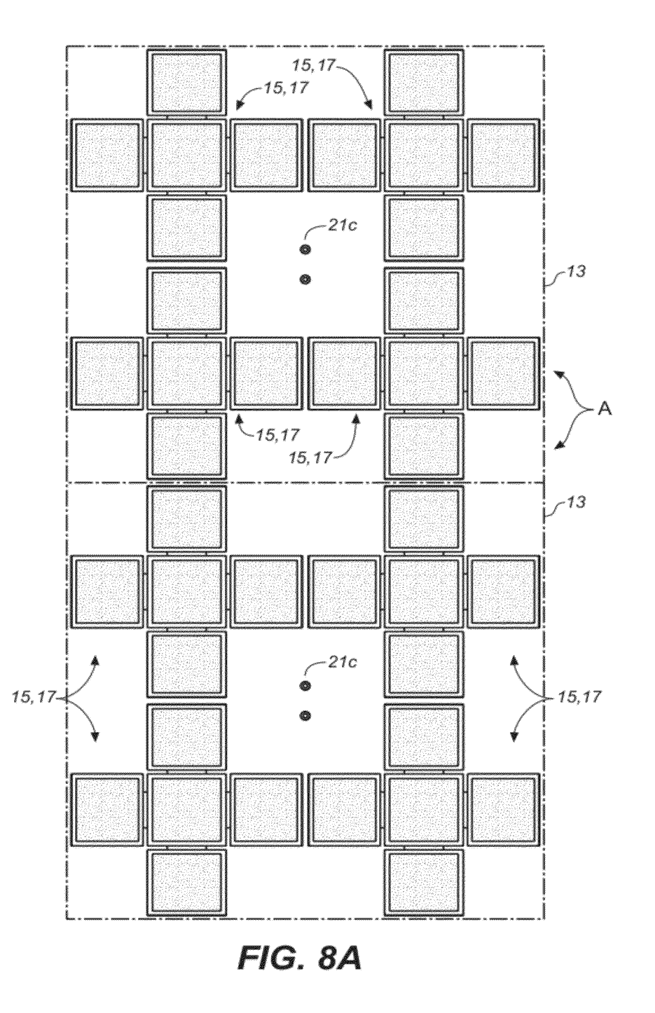

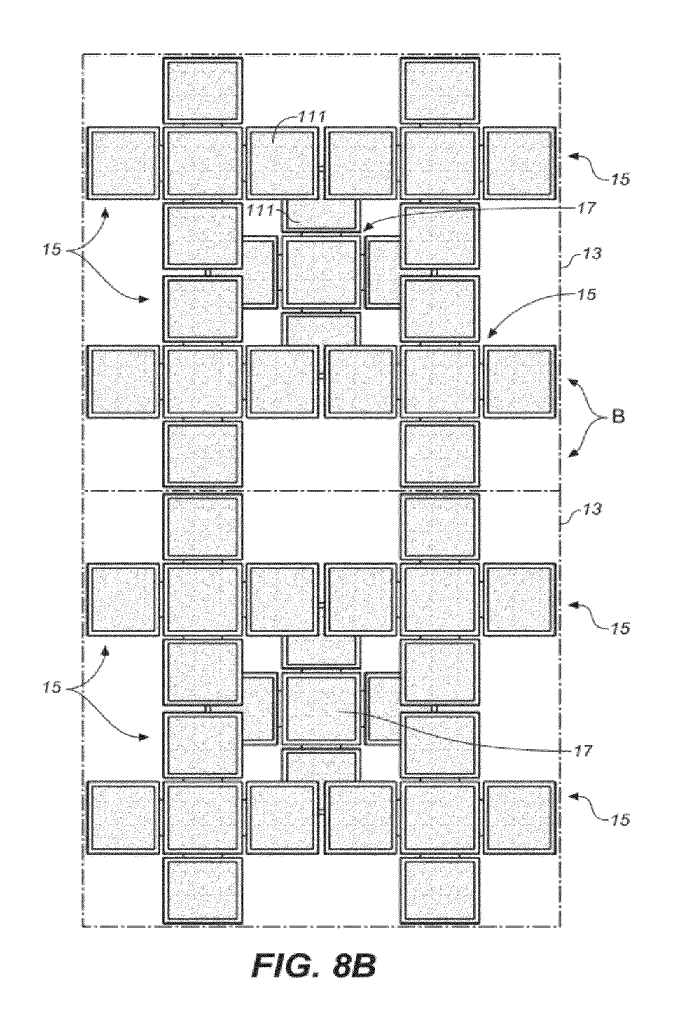

FIGS. 8A-12 show examples of how the above-described small profile, low luminance lighting modules and differently configured ceiling driver panels can be used to create different ceiling lighting system configurations, and particularly configurations that achieve high application efficiencies in accordance with the invention. In each case the connection points on the bottom of the panel are arrayed in the x-y pane of the panel to allow the light modules to be arrayed on the panel in the x-y plane in desired groupings or clusters overhead task areas, including tight clusters for placing a greater amount of light on particular task areas for increased application efficiency. FIG. 8A shows two side-by-side driver panels (represented by dashed lines 13) with the same array of five electrical connectors for providing five connection points on each panel. In the ceiling lighting system configuration shown in FIG. 8A, four five-panel light modules, either arm-down modules 15 or arm-up modules 17 or a combination thereof, are plugged into the four corner connection points of each driver panel to produce a layout of module cross rows denoted as layout “A”. The center connector means 21c of each panel is unused and can be covered by finishing elements such as the cap plugs 91 shown in FIG. 7B. FIG. 8B shows the same side-by-side driver panels 13, but with five light modules plugged into each panel, that is, with a five-panel light module plugged into each connection point on the panel, resulting in a cluster of modules denoted as layout “B.” Here, the four corner light modules are suitably arm-down modules 15 with the center module being an arm-up light module 17. This will allow the outboard OLED panels of the center arm-up light module to fit under the outboard OLED panels of the four corner light modules.

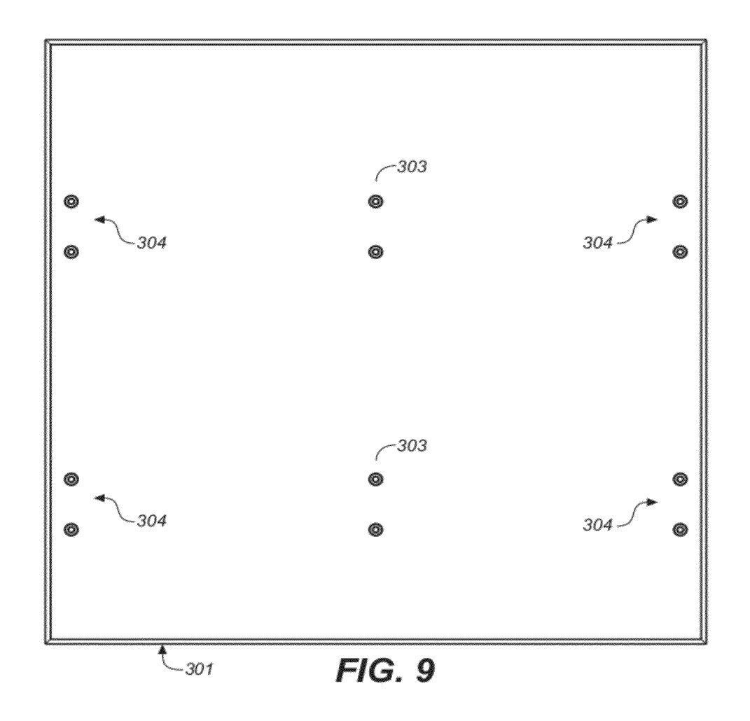

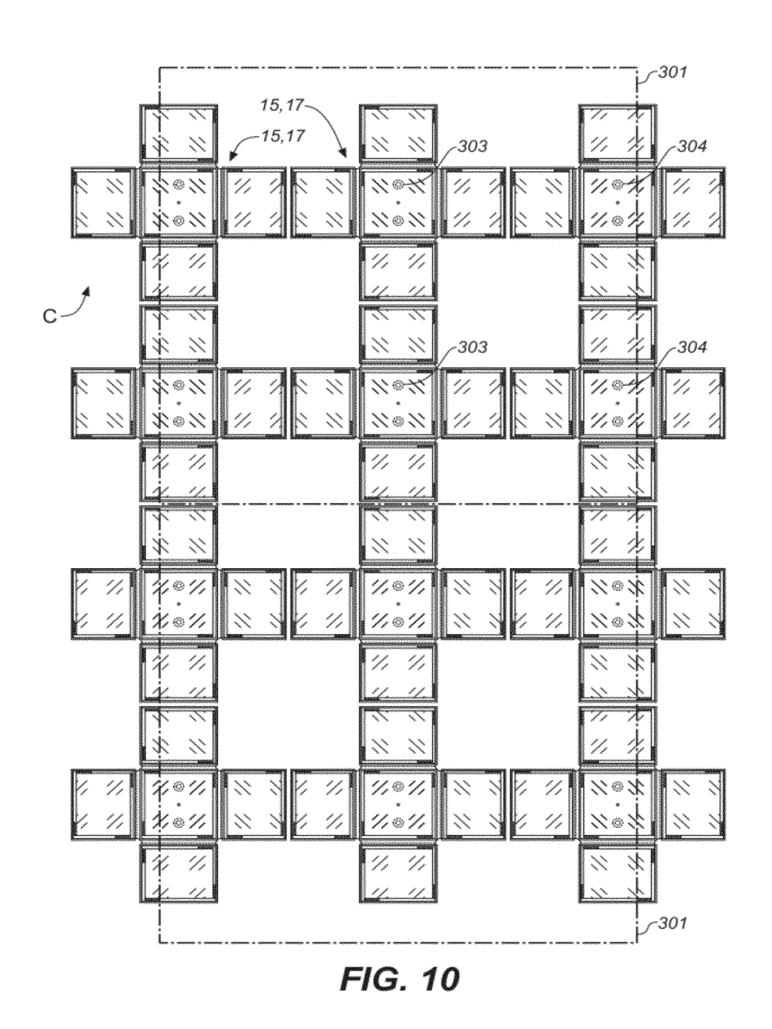

FIG. 9 illustrates a driver panel 301 having a different arrangement of electrical connectors 303, 304 for providing different connection points on the panel. In this case six connection points are provided for up to six light modules. They include connection points at 304 closely adjacent the perimeter edge of the driver panel to allow a light module to overlap ceiling grid panels. An example of ceiling lighting system configuration that can be created with these driver panels is shown in FIG. 10, and is denoted as layout “C.” The light panels plugged into the adjacent panels 301 can be either arm-up or arm-down versions of the light modules 15, 17 above described or a combination thereof.

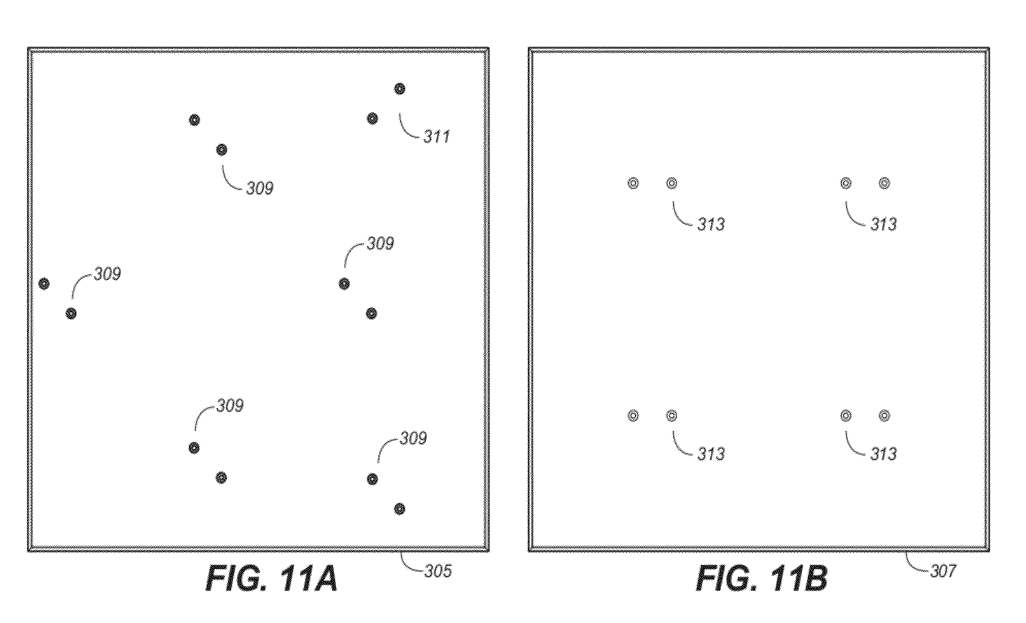

FIGS. 11A and 11B show driver panels 305, 307 with yet two further exemplary arrangements of electric connectors. In FIG. 11A the electrical connector 309, 311 are angled relative to the perpendicular axes of the panel with one pair of connectors, connector pair 311, being rotated ninety degrees relative to the other connects 309. In FIG. 11B, the driver panel is shown with four pairs of connectors 313 oriented parallel to one perpendicular axis of the panel.

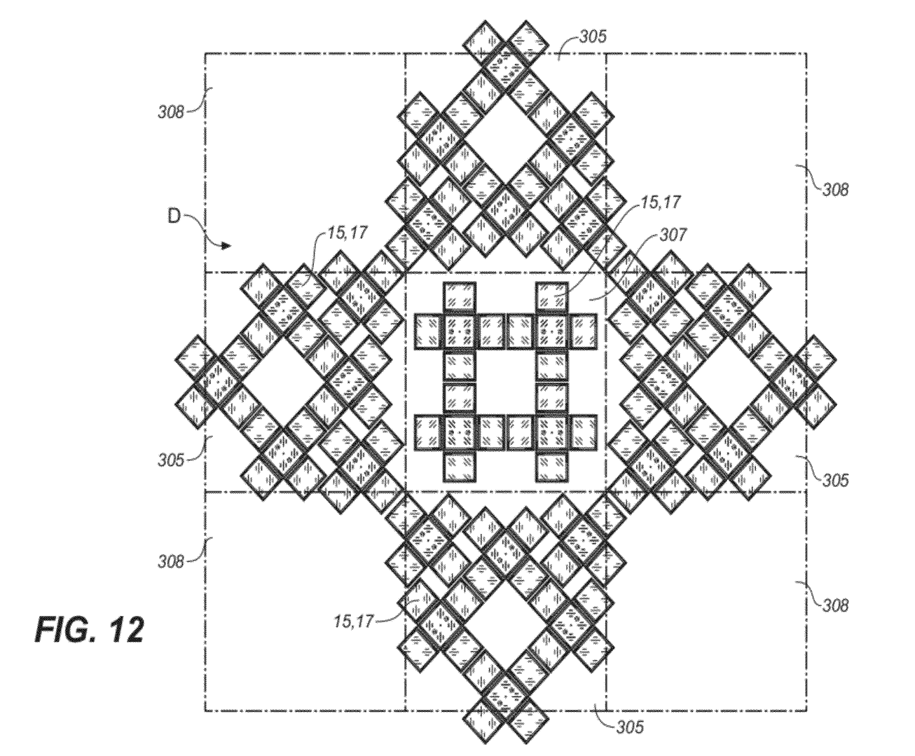

FIG. 12 shows an exemplary ceiling lighting system having a plurality of lighting modules configured in an arrangement, denoted layout “D,” created using a combination of the different driver panels. Nine contiguous ceiling panels are represented by dashed line squares 305, 307 and 308. Dashed squares 305 represent driver panels having the connection points shown in FIG. 11A, while the dashed center square 307 represents a ceiling panel having the connection points shown in FIG. 11B. Dashed squares 308 represent ceiling panels that could be additional driver panels or ceiling panels that are not driver panels, such as acoustic ceiling tiles.

The foregoing examples of creating clusters of low luminance lighting modules to achieve high application efficiencies in a space are illustrative and not intended to limit the method or system of invention for more efficiently illuminating a space. Small footprint lighting modules having a low lumen output other than the five OLED panel lighting modules described herein could be used, provided that they can be configured overhead the space in different placement densities including high placement densities.

While the invention has been described in considerable detail in the foregoing specification, it will be appreciated that variations of the method and system of the invention not specifically described herein, but which are within the scope and spirit of the invention, would be apparent to persons skilled in the art based on the description provided herein.

1. A method for illuminating a space, comprising
a. sectioning the space to be illuminated into lighting requirement areas having different illumination requirements,
b. determining the area of each lighting requirement area,
c. determining the minimum number of lumens required to illuminate each lighting requirement area based on the determined area of the lighting requirement area and a defined minimum illumination requirement for the lighting requirement area,
d. providing a plurality of lighting modules capable of delivering lumens into the space from overhead positions, each of said lighting fixture modules having a low lumen output, and all of said lighting fixture modules capable of being configured overhead the space in different placement densities including high placement densities, wherein a different amount of lumens can be delivered into the space at different overhead placement positions depending on the placement densities of the lighting modules at their placement positions,
e. determining the number and placement density of lighting modules needed over each lighting requirement area to produce a desired number of lumens for such lighting requirement area, and
f. placing low lumen lighting modules overhead each of said lighting requirement areas in the numbers and placement densities determined in accordance with step (e).

2. The method of claim 1 wherein each of said lighting modules has a lumen output of less than about 400 lumens.

3. The method of claim 1 wherein each of said lighting modules has a lumen output of between about 300 lumens and about 400 lumens.

4. The method of claim 1 wherein each of said lighting modules has a maximum perimeter dimension defining a footprint that allows the lighting module to be occupy an overhead space of about one foot by one foot or less.

5. The method of claim 1 wherein each said lighting modules deliver lumens into the space in a substantially lambertian distribution pattern.

6. The method of claim 1 wherein the space to be illuminated is an indoor space, such as an open office or retail space, which includes task areas and non-task areas having different lighting requirements, and wherein lighting modules are placed overhead each of said lighting requirement areas in the numbers and placement densities needed to produce a desired number of lumens for each such task area and non-task area.

7. The method of claim 1 wherein said plurality of the lighting modules provides the majority of the illumination required in the space.

8. A method for illuminating a space, comprising
a. sectioning the space to be illuminated into lighting requirement areas having different illumination requirements,
b. determining the area of each lighting requirement area,
c. determining the minimum number of lumens required to illuminate each lighting requirement area based on the determined area of the lighting requirement area and a defined minimum illumination requirement for the lighting requirement area,
d. providing a plurality of lighting modules having a planar light emitting surface capable of delivering lumens into the space from overhead positions, each of said lighting fixture modules having a lumen output of less than about 400 lumens and being adapted to deliver lumens into the space in a substantially lambertian distribution pattern, and each of said lighting modules having a maximum perimeter dimension defining a footprint that allows the lighting module to be occupy an overhead space of about one foot by one foot or less, and all of said lighting fixture modules being capable of being configured overhead the space in different placement densities including high placement densities, wherein a different amount of lumens can be delivered into the space at different overhead placement positions depending on the placement densities of the lighting modules at their placement positions,
e. determining the number and placement density of lighting modules needed over each lighting requirement area to produce a desired number of lumens for such lighting requirement area, and
f. placing low lumen lighting modules overhead each of said lighting requirement areas in the numbers and placement densities determined in accordance with step (e).

9. The method of claim 8 wherein the space to be illuminated is an indoor space, such as an open office or retail space, which includes task areas and non-task areas having different lighting requirements, and wherein lighting modules are placed overhead each of said lighting requirement areas in the numbers and placement densities needed to produce a desired number of lumens for each such task area and non-task area.

10. The method of claim 9 wherein each of said lighting modules has a lumen output of between about 300 lumens and about 400 lumens.

11. A system for illuminating a space having an overhead ceiling, comprising
a plurality of lighting modules, each of said lighting fixture modules having a low lumen output, and all of said lighting fixture modules capable of being configured in different overhead placement densities, including high placement densities, wherein a different amount of lumens can be delivered into the space at different overhead placement positions depending on the number and placement densities of the lighting modules at their placement positions, and
means for mounting said plurality of lighting modules on the ceiling overhead different lighting requirement areas of the space which have different illumination requirements, said mounting means permitting the lighting modules to be placed together on the ceiling at different placement densities, including high placement densities, to deliver a different amount of lumens to the different lighting requirement areas of the space.

12. The system of claim 11 wherein each of said lighting modules has a lumen output of less than about 400 lumens.

13. The system of claim 12 wherein each of said lighting modules has a lumen output of between about 300 lumens and about 400 lumens.

14. The system of claim 12 wherein each of said lighting modules has a maximum perimeter dimension defining a footprint that allows the lighting module to occupy an overhead space of about one foot by one foot or less.

15. The system of claim 12 wherein each said lighting modules have a diffuse light output for delivering lumens into the space in a substantially lambertian distribution pattern.

16. The system of claim 12 wherein said lighting modules have light sources with planar light emitting surfaces.

17. The system of claim 12 wherein the light sources of said lighting modules are OLEDs.
